(19) United States
(12) Patent Application Publication
(10) Pub. No.: US 2026/0057135 A1
(43) Pub. Date: Feb. 26, 2026

(54) Automated Method for Mapping Atmospheric Density from Satellite Data

(71) Applicant: Kayhan Space Corp., Boulder, CO (US)

(72) Inventors: Siamak HESAR, Lafayette, CO (US); Araz FEYZI, Ashburn, VA (US); Vishal RAY, Westminster, CO (US)

(21) Appl. No.: 18/766,332

(22) Filed: Jul. 8, 2024

Related U.S. Application Data
(60) Provisional application No. 63/525,497, filed on Jul. 7, 2023.

(51) Int. Cl. G06F 30/20

(52) U.S. Cl. CPC G06F 30/20

(57) ABSTRACT

One variation of a method includes: accessing a first series of mission data of a satellite including a first data subset corresponding to the satellite traversing a first orbit on a first arc of an orbital path at a first attitude; accessing a second series of mission data of the satellite including a second data subset corresponding to the satellite traversing a second orbit on the first arc of the orbital path at a second attitude; based on a virtual representation of the satellite, calculating a first frontal area of the satellite during the first orbit and a second frontal area during the second orbit; calculating an atmospheric density proximal the first arc based on the first and second data subsets and the first and second frontal areas; and generating an atmospheric density gradient map representing the atmospheric density proximal the first arc.

### CROSS-REFERENCE TO RELATED APPLICATIONS

This application claims the benefit of U.S. Provisional Application No. 63/525,497, filed on 7 Jul. 2023, which is incorporated in its entirety by this reference.

### TECHNICAL FIELD

This invention relates generally to the field of atmospheric mapping and more specifically to a new and useful automated method for mapping atmospheric density from satellite data.

### BRIEF DESCRIPTION OF THE FIGURES

FIG. 1 is a flowchart representation of one variation of a method;

FIG. 2 is a flowchart representation of one variation of the method;

FIG. 3 is a flowchart representation of one variation of the method; and

FIG. 4 is a flowchart representation of one variation the method.

### DESCRIPTION OF THE EMBODIMENTS

The following description of embodiments of the invention is not intended to limit the invention to these embodiments but rather to enable a person skilled in the art to make and use this invention. Variations, configurations, implementations, example implementations, and examples described herein are optional and are not exclusive to the variations, configurations, implementations, example implementations, and examples they describe. The invention described herein can include any and all permutations of these variations, configurations, implementations, example implementations, and examples.

### 1. Method: Atmospheric Density from Consecutive Orbits

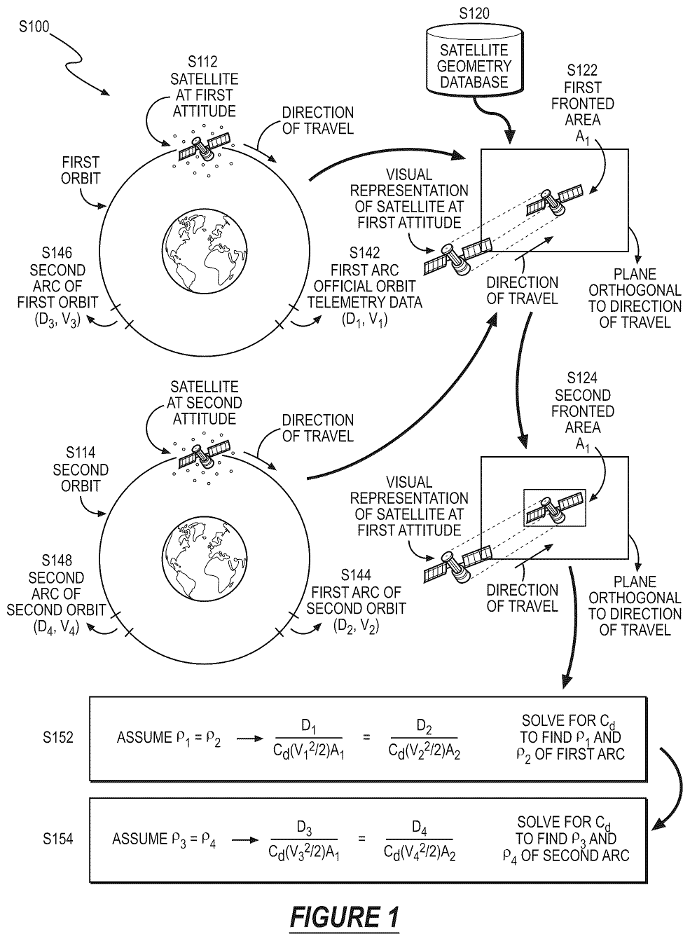

As shown in FIGS. 1-4, a method S100 includes: accessing a first series of mission data of a first satellite traversing a first orbit on a first orbital path at a first altitude and at a first attitude during a first time period in Block S112; accessing a second series of mission data of the first satellite traversing a second orbit on the first orbital path at the first altitude and at a second attitude during a second time period in Block S114; accessing a first virtual representation of the first satellite in Block S120; calculating a first frontal area of the first satellite during the first orbit based on the first virtual representation of the first satellite and the first attitude in Block S122; calculating a second frontal area of the first satellite during the second orbit based on the first virtual representation of the first satellite and the second attitude in Block S124; selecting a first subset of mission data, from the first series of mission data, corresponding to a first arc of the first orbital path in Block S142; and selecting a second subset of mission data, from the second series of mission data, corresponding to the first arc of the first orbital path in Block S144. The method S100 further includes: calculating a first atmospheric density proximal the first arc of the first orbital path based on the first subset of mission data, the second subset of mission data, the first frontal area, and the second frontal area in Block S152; and generating an atmospheric density gradient map representing the first atmospheric density proximal the first arc of the first orbital path at the first altitude in Block S162.

As shown in FIG. 1, one variation of the method S100 includes: accessing a first series of mission data of a first satellite traversing a first orbit on a first orbital path corresponding to a first altitude, at a first attitude in Block S112; accessing a second series of mission data of the first satellite traversing a second orbit, on the first orbital path and succeeding the first orbit, at a second attitude in Block S114; accessing a first virtual representation of the first satellite in Block S120; calculating a first frontal area of the first satellite during the first orbit based on the first virtual representation of the first satellite and the first attitude in Block S122; and calculating a second frontal area of the first satellite during the second orbit based on the first virtual representation of the first satellite and the second attitude in Block S124.

In this variation, the method S100 further includes: selecting a first subset of mission data, from the first series of mission data, corresponding to a first arc of the first orbital path in Block S142; selecting a second subset of mission data, from the second series of mission data, corresponding to the first arc of the first orbital path in Block S144; and calculating a first atmospheric density proximal the first arc on the first orbital path based on the first subset of mission data, the second subset of mission data, the first frontal area, and the second frontal area in Block S152.

In this variation, the method S100 further includes: selecting a third subset of mission data, from the first series of mission data, corresponding to a second arc of the first orbital path in Block S146; selecting a fourth subset of mission data, from the second series of mission data, corresponding to the second arc of the first orbital path in Block S148; and calculating a second atmospheric density proximal the second arc on the first orbital path based on the third subset of mission data, the fourth subset of mission data, the first frontal area, and the second frontal area in Block S154.

In this variation, the method S100 further includes generating an atmospheric density gradient map representing the first atmospheric density proximal the first arc of the first orbital path at the first altitude and the second atmospheric density proximal the second arc of the first orbital path at the first altitude in Block S162.

### 1.1 Variation: Satellite Area×Drag Coefficient Function

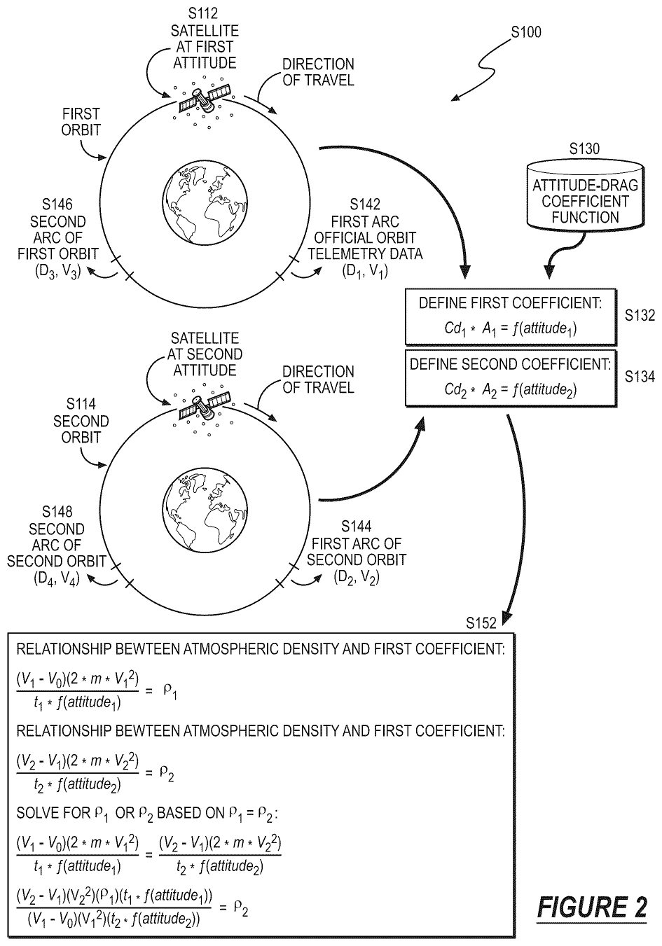

As shown in FIG. 2, one variation of the method S100 includes: accessing a first series of mission data of a first satellite traversing a first orbit on a first orbital path at a first altitude and at a first attitude during a first time period in Block S112; accessing a second series of mission data of the first satellite traversing a second orbit on the first orbital path at the first altitude and at a second attitude during a second time period in Block S114; accessing a first function relating attitudes of the first satellite to coefficients representing products of frontal areas and coefficients of drag of the first satellite in Block S130; calculating a first coefficient of the first satellite during the first orbit based on the first function and the first attitude in Block S132; calculating a second coefficient of the first satellite during the second orbit based on the first function and the second attitude in Block S134; selecting a first subset of mission data, from the first series of mission data, corresponding to a first arc of the first orbital path in Block S142; and selecting a second subset of mission data, from the second series of mission data, corresponding to the first arc of the first orbital path in Block S144.

In this variation, the method S100 further includes calculating a first atmospheric density proximal the first arc on the first orbital path based on the first subset of mission data, the second subset of mission data, the first coefficient, and the second coefficient in Block S152; and generating an atmospheric density gradient map representing the first atmospheric density proximal the first arc of the first orbital path at the first altitude in Block S162.

### 1.2 Variation: Second Satellite

In one variation, the method S100 further includes: accessing a third series of mission data of a second satellite traversing a third orbit, on a second orbital path corresponding to a second altitude different from the first altitude, at a third attitude in Block S116; accessing a fourth series of mission data of a second satellite traversing a fourth orbit, on the second orbital path and succeeding the third orbit, at a fourth attitude in Block S118; accessing a second virtual representation of the second satellite; calculating a third frontal area of the second satellite during the third orbit based on the second virtual representation of the second satellite and the third attitude; and calculating a fourth frontal area of the second satellite during the fourth orbit based on the second virtual representation of the second satellite and the fourth attitude in Block S121.

In this variation, the method S100 further includes: selecting a fifth subset of mission data, from the third series of mission data, corresponding to a third arc of the second orbital path; selecting a sixth subset of mission data, from the fourth series of mission data, corresponding to the third arc of the second orbital path; and calculating a third atmospheric density proximal the third arc on the third orbital path based on a) the fifth subset of mission data, b) the sixth subset of mission data, c) the third frontal area, and d) the fourth frontal area.

This variation of the method S100 further includes generating the atmospheric density gradient map that further represents: the third atmospheric density proximal the third arc of the second orbital path at the second altitude; and the second atmospheric density proximal the second arc of the second orbital path at the second altitude.

1.3 Method: Atmospheric Density from Consecutive Arcs within an Orbit

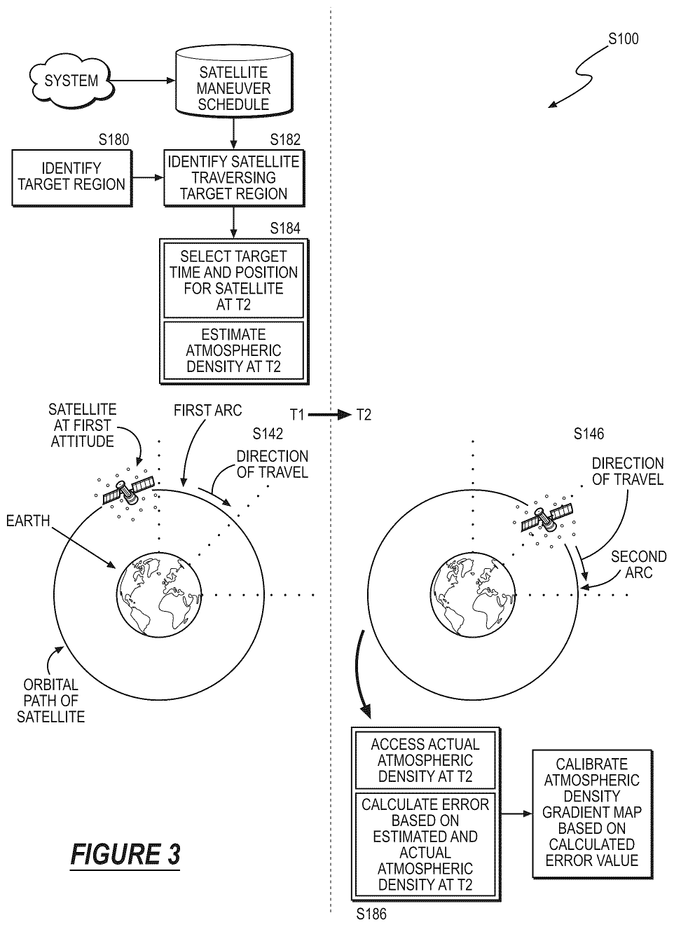

In one variation shown in FIG. 3, the method S100 includes calculating an atmospheric density of consecutive arcs within one orbit. This variation of the method includes: accessing a first series of mission data of a first satellite traversing a first arc of a first orbit, on a first orbital path corresponding to a first altitude, at a first attitude in Block S112; accessing a second series of mission data of the first satellite traversing a second arc of the first orbit, adjacent and succeeding the first arc, at a second attitude in Block S114; accessing a first virtual representation of the first satellite in Block S120; calculating a first frontal area of the first satellite traversing the first arc of the first orbit based on the first virtual representation of the first satellite and first attitude in Block S122; and calculating a second frontal area of the first satellite traversing the second arc of the first orbit based on the first virtual representation of the first satellite and second attitude in Block S124.

In this variation, the method S100 further includes calculating a first average atmospheric density across a first composite arc, comprising the first arc and the second arc, on the first orbital path based on: the first series of mission data; the second series of mission data; the first frontal area; and the second frontal area in Block S152. In this variation, the method also includes generating an atmospheric density gradient map representing the first average atmospheric density proximal the first composite arc of the first orbital path at the first altitude in Block S162.

In this variation, the method S100 can further include: accessing a third series of mission data of a second satellite traversing a third arc of a second orbit, on a second orbital path corresponding to a second altitude, at a second attitude in Block S116; accessing a fourth series of mission data of the second satellite traversing a fourth arc of the second orbit, adjacent and succeeding the third arc, at a second attitude in Block S118; and accessing a second virtual representation of the second satellite in Block S121.

In this variation, the method S100 can further include: calculating a third frontal area of the second satellite traversing the third arc of the second orbit based on the second virtual representation of the second satellite and third attitude; calculating a fourth frontal area of the second satellite traversing the second arc of the second orbit based on the second virtual representation of the second satellite and fourth attitude; and calculating a second average atmospheric density across a second composite arc-including the third arc and the fourth arc-on the second orbital path based on a) the third series of mission data, b) the fourth series of mission data, c) the third frontal area, and d) the fourth frontal area in Block S156.

In this variation, the method S100 can further include generating the atmospheric density gradient map that further represents the second average atmospheric density proximal the second composite arc of the second orbital path at the second altitude in Block S162.

### 2. Applications

Generally, the method S100 is executed by a system (e.g., a terrestrial computer server or computer network; an on-board aerial or satellite computer or computer network) in communication with a population of satellites; a satellite operator (e.g., an automated and/or manual satellite operation network) responsible for controlling orbital trajectories of the population of satellites; and/or a satellite tracking database.

The system executes Blocks of the method S100: to access trajectory and attitude data of a satellite before and after an attitude change of the satellite; to derive an atmospheric drag of the satellite proximal a celestial location (e.g., latitude, longitude, altitude with a terrestrial coordinate system of the Earth) of this attitude change; and to interpret an atmospheric density near this celestial location based on derived frontal areas of the satellite before and after the attitude change. The system can further: repeat this process for many (e.g., hundreds, thousands) satellites in the satellite population over time in order to derive atmospheric densities near many celestial locations; compile these atmospheric densities into a three-dimensional map of atmospheric densities based on their corresponding celestial locations; and interpolate an atmospheric density between these derived atmospheric densities to form a gradient or mesh of current atmospheric densities within this three-dimensional atmospheric density map. The system can additionally or alternatively: repeat this process to create multiple three-dimensional atmospheric density maps over time based on trajectory and attitude data of these satellites, such as collected within discrete time intervals; and can extrapolate future atmospheric densities at particular celestial locations based on past and/or current atmospheric density maps.

In particular, the system can execute Blocks of the method to: access trajectory data (e.g., timeseries celestial positions, velocities) of a satellite traversing all or a segment of an orbital path at two different attitudes; and then estimate atmospheric density within this segment of the orbital path based on these trajectory data before and after the change in the satellite's attitude. The system can decouple the atmospheric density from the drag coefficient based on variations of the attitude. For example, the system can decouple atmospheric density and the drag coefficient by: accessing a first set of mission data for a satellite at a first position before an attitude change (e.g., at a first attitude), accessing a second set of mission data for the satellite at a second position after the attitude change (e.g., at a second attitude) wherein the change in atmospheric density is significantly smaller (e.g., 1-10% of the total change) than the change in drag-coefficient between the first and second position; calculating the drag, position and velocity of the satellite at each position from the first and second sets of mission data; calculating a first and a second frontal area of the satellite based on the first and second attitudes; and solving for a value of the drag coefficient with the drag, velocity, and frontal area at the first and second positions and based on the value of the drag coefficient calculating the atmospheric density between the first and second position. Therefore, the method can derive an atmospheric density at a region of the atmosphere-containing this segment of the orbital path traversed by the satellite before and after the attitude change-based on mission data collected by the satellite.

The system can then: predict a future atmospheric drag force on another satellite passing near this atmospheric region based on this derived atmospheric density; and/or combine this atmospheric density with atmospheric densities derived from telemetry and attitude data collected by other satellites executing attitude changes in other atmospheric regions to generate a (comprehensive) map of atmospheric densities over a range of altitudes and spanning many orbital paths around the Earth. A (human or automated) satellite operator may thus plan future attitude changes or thrust operations for orbit maintenance or collision avoidance based on higher accuracy predictions of atmospheric densities.

2.1 Passive v. Active Satellite Control+Preemptive v. Retroactive Data

Generally, the system can execute Blocks of the method: to actively schedule (or “trigger”) attitude changes within a population of satellites, such as near target celestial locations for which extant atmospheric densities were derived from outdated satellite mission data; and to preemptively queue recordation and access to mission data from these satellites before and after these scheduled attitude changes. For example, the system can: actively schedule attitude changes within a population of satellites in order to generate satellite mission data from which the system can derive atmospheric densities within select atmospheric regions; and then update oldest atmospheric densities in an atmospheric density model to reflect these new derived atmospheric densities. Thus, the system collects mission data to generate and update an atmospheric density models can be updated to reflect improved accuracy drag-coefficient data.

Additionally or alternatively, the system can execute Blocks of the method: to access a schedule of planned attitude changes within a population of satellites, such as published by a commercial satellite operator; and to preemptively request recordation and access to mission data from these satellites before and after these scheduled attitude changes. For example, the system can: access a schedule of preplanned attitude changes within a population of satellites; request pre- and post-attitude-change mission data from these satellites; derive atmospheric densities within select atmospheric regions based on mission data; and then opportunistically update atmospheric densities in the current atmospheric density model to reflect these new derived atmospheric densities.

Additionally or alternatively, the system can execute Blocks of the method: to access a database of past or historical satellite mission data; to detect attitude changes reflected in these historical mission data; and to derive past atmospheric densities based on historical mission data before and after these detected attitude changes. For example, the system can: derive historical atmospheric densities from weeks, months, years, or decade of historical satellite mission data; generate historical three-dimensional atmospheric density maps based on these historical atmospheric densities, such as one historical three-dimensional atmospheric density map per past one-week or one-month time interval. The system can then extrapolate a current or future atmospheric density map by inputting historical density trends to the atmospheric models.

For example, the system can actively change the attitude of a satellite by generating and transmitting a signal to the satellite indicating maneuver instructions to change attitude. Conversely, the system can: passively access a timeseries of satellite mission data; detect an attitude change from the mission data; extract a first set of mission data at a first time preceding an attitude change (e.g., when the satellite is at a first attitude); and extract a second set of mission data at a second time following the attitude change (e.g., when the satellite is at a second attitude) to calculate the atmospheric density of the region decoupled from the drag-coefficient between the positions of the satellite at the first and second times.

The system can additionally select a target region within the atmospheric density gradient map that does not include a derived atmospheric density and actively maneuver a satellite to the target region or passively detect a satellite with a trajectory that passes through the target region to collect data. Further, the system can interpolate between existing mission data sets at regions adjacent to the target region to estimate an average atmospheric density of the target region.

In one variation, the system can track multiple satellites within the same region (e.g., at the same altitude and within 1° of latitude and 1° of longitude) within a time interval (e.g., 3-24 hours) and iteratively calculate the atmospheric density of the region based on data from each satellite. The system iteratively executes the foregoing process and updates the atmospheric density gradient map to converge on an atmospheric density value with minimal error.

The system can further access mission data from a population of satellites (e.g., 1000 satellites) orbiting the Earth to frequently update the atmospheric density gradient map (e.g., re-calculate a density value of a region of the atmosphere once per minute). The system can additionally access data from unused and/or retired satellites (e.g., satellites that no longer perform the initially intended function but still communicate mission data to systems on Earth) to increase the set of usable data for the atmospheric density gradient map. Therefore, the system generates and maintains the atmospheric density gradient map with updated data to enable accurate satellite trajectory calculations.

### 3. Terms

An “orbital path” is referred to herein as a defined, repeating trajectory (or “path”) that a satellite follows around another, larger object (e.g., a defined trajectory around Earth followed by a particular satellite due to gravity).

An “orbit” is referred to herein as a single revolution of an orbital path by a satellite.

An “arc” is referred to herein as a segment or an entirety of an orbit (e.g., an arc can include 1° of a 360° orbit).

A “set of satellite mission data” is referred to herein as satellite ephemeris data (e.g., trajectory data, satellite velocity, past satellite coordinates, current satellite coordinates, future satellite coordinates, etc.) and/or telemetry data (e.g., orbital parameters, satellite health reports, operational status, etc.) corresponding to a particular satellite.

### 4. System

In one implementation, the system includes a server or a set of servers in communication with (e.g., via an API) a satellite tracking system and/or a set of satellite operators via the internet. Additionally, the system can communicate with on-board satellite computers-such as directly or via a satellite or terrestrial network-to receive real-time or stored mission data. Additionally or alternatively, the system can retrieve satellite mission data from a satellite mission database.

In one example, the system includes multiple software modules to: generate attitude change maneuver instructions; transmit attitude change maneuver instructions; request and access satellite maneuver schedule data; passively monitor timeseries of telemetry satellite data; calculate forces on a satellite; generate the atmospheric density gradient map; and predict future atmospheric density conditions.

4.1 Atmospheric Density v. Drag

The relationship between atmospheric density, the drag force, and the drag coefficient is defined by equation [1]:

$$\frac{{C}_{d} ρ {V}^{2} A}{2} = D \qquad [ 1 ]$$

wherein: C_{d} is the drag coefficient; p is atmospheric density; V is velocity of the satellite; A is the frontal area of the satellite (e.g., the surface area of the satellite the drag force acts on); and D is the drag force. The system can calculate the drag force (D) and velocity (V) of the satellite from mission data.

### 4.1.1 Virtual Representation of Satellite

In one variation, the method S100 includes: accessing a first virtual representation of the first satellite in Block S120; calculating a first frontal area of the first satellite during the first orbit based on the first virtual representation of the first satellite and the first attitude in Block S122; and calculating a second frontal area of the first satellite during the second orbit based on the first virtual representation of the first satellite and the second attitude in Block S124. In this variation, the system can access a database hosting a corpus of satellite data (e.g., CAD models) and extract a series of satellite characteristics in Block S120; calculate a first frontal area (A) for a particular satellite at a first attitude in Block S122; and calculate a second frontal area (A) for the satellite at a second attitude in Block S124.

For example, the system can calculate frontal area (A) from the attitude and satellite characteristics (e.g., by projecting a three-dimensional representation of the satellite at the attitude onto a plane orthogonal to the direction of motion of the satellite and finding the area of the projection). Therefore, the system derives the product of Cap based on mission data and satellite characteristics.

In this variation, the system executes Blocks of the method S100 to calculate a value of C_{d} based on mission data from a first time when the satellite is at a first attitude and mission data from a second time when the satellite is at a second altitude wherein the atmospheric density is constant from the position the satellite occupies at the first time and the position the satellite occupies at the second time. Furthermore, in this variation, the system decouples the drag coefficient (C_{d}) from atmospheric density (φ by solving for C_{d} with two sets of mission data over a region (e.g., an arc of an orbit) or constant atmospheric density. In this variation, the system iteratively calculates atmospheric density by solving equation [1] with values from subsequent sets of mission data at subsequent times, positions, and attitudes.

In one example, the system can: access the virtual representation of the satellite to calculate the first frontal area of the satellite. The system can: access a three-dimensional representation (e.g., a CAD map of the satellite); detect a direction of motion of the satellite from the mission data; select a plane orthogonal to the direction of motion in the first series of mission data; orient the three-dimensional representation of the satellite relative to the plane based on the first attitude; and project a two-dimensional representation of the three-dimensional representation of the satellite onto the plane.

Furthermore, the system can: derive a first angular acceleration (i.e., change in angular velocity) and a first velocity of a satellite-occupying a first attitude while approaching a celestial location of an attitude change-from a first set of mission data; derive a second angular acceleration (i.e., change in angular velocity) and a second velocity of a satellite-occupying a second attitude while departing from a celestial location of attitude change-from a second set of mission data; and derive a first and a second atmospheric drag force acting on the satellite from the first and the second angular accelerations.

The system can then solve for C_{d} based on the atmospheric drag force, velocity, and frontal areas at the first and second position of the satellite over a region of minimally changing atmospheric density (e.g., 1-10% change) based on equations [2]-[6]:

$${C}_{d} {ρ}_{1} = \frac{2 * {D}_{1}}{{V}_{1}^{2} {A}_{1}} \qquad [ 2 ]$$

$${C}_{d} {ρ}_{2} = \frac{2 * {D}_{2}}{{V}_{2}^{2} {A}_{2}} \qquad [ 3 ]$$

$${ρ}_{1} = {ρ}_{2} \qquad [ 4 ]$$

$$\frac{2 * {D}_{1}}{{ρ}_{1} {V}_{1}^{2} {A}_{1}} = \frac{2 * {D}_{2}}{{ρ}_{2} {V}_{2}^{2} {A}_{2}} \qquad [ 5 ]$$

$${C}_{d} = \frac{{D}_{1} {A}_{2} {V}_{2}^{2}}{{D}_{2} {A}_{1} {V}_{1}^{2}} \qquad [ 6 ]$$

where: C_{d} is the drag coefficient; ρ₁ is the first atmospheric density at the first attitude; ρ₂ is the first atmospheric density at the second attitude; V₁² is the first velocity; V₂² is the second velocity; A₁ is the first frontal area; A₂ is the second frontal area; D₁ is the first atmospheric drag force; and D₂ is the second atmospheric drag force. The system can then calculate an atmospheric density proximal the first arc of the first orbital path at the first altitude based on the value of C_{d} by solving equation [1].
4.1.2 Function: Attitude v. Frontal Areas×Drag Coefficient

In another variation, the method S100 can include: accessing a function relating attitudes of the satellite to coefficients representing products of frontal areas and coefficients of drag of the satellite in Block S130; calculating a first coefficient of the satellite during the first orbit based on the function and the first attitude in Block S132; and calculating a second coefficient of the satellite during the second orbit based on the function and the second attitude in Block S134.

In this variation, the system can derive a function relating attitudes of a satellite to coefficients representing products of frontal areas and coefficients of drag of the satellite (e.g., in response to absence of a virtual representation of the satellite). Therefore, the system derives a function of change in drag coefficient C_{d} to a change in attitude based on mission data and satellite characteristics.

In particular, in this variation, the system executes Blocks of the method S100 to derive a function of change in drag coefficient C_{d} to a change in attitude based on mission data from a first calibration period when the satellite is at a first attitude and mission data from a second calibration period when the satellite is at a second attitude wherein the atmospheric density and the atmospheric drag are constant from the first position the satellite occupies at the first time and the second position the satellite occupies at the second time. Furthermore, in this variation, the system derives the function by detecting changes in frontal area between two sets of mission data over a region (e.g., an arc of an orbit). In this variation, the system iteratively calculates atmospheric density by solving equation [1] based on coefficients from subsequent sets of mission data at subsequent times, positions, and attitudes.

In one example, the system can: access a first series of mission data including a first velocity, a first pitch, a first yaw, a first roll, a first configuration, and a first direction of motion of the satellite traversing a first orbit on a first orbital path at a first altitude and at a first attitude during a first calibration period; and access a second series of mission data including a second velocity, a second pitch, a second yaw, a second roll, a second configuration, and a second direction of motion of the first satellite traversing a second orbit on the first orbital path at the first altitude and at a second attitude during a second calibration period.

In this example, the system can detect a change in frontal area of the satellite between the first attitude and the second attitude based on: the first yaw, the first pitch, the first roll, the first configuration, the second yaw, the second pitch, the second roll, and the second configuration; and derive the function based on the first velocity, the second velocity, and the change in frontal area of the satellite. In this example, the system iteratively derives the function based on mission data from subsequent sets of mission data at subsequent times, positions, and attitudes.

The system can then solve for the atmospheric drag force based on the change in velocity, and the function attitudes of the first satellite to coefficients representing products of frontal areas and coefficients of drag of the first satellite at the first and second position of the satellite over a region of minimally changing atmospheric density (e.g., 1-10% change) based on equations [7]-[11]:

$$\frac{( {V}_{1} - {V}_{0} ) ( 2 * m * {V}_{1}^{2} )}{{t}_{1} * f ( {attitude}_{1} )} = {ρ}_{1} ; \qquad [ 7 ]$$

$$\frac{( {V}_{2} - {V}_{1} ) ( 2 * m * {V}_{2}^{2} )}{{t}_{2} * f ( {attitude}_{2} )} = {ρ}_{2} ; \qquad [ 8 ]$$

$${ρ}_{1} = {ρ}_{2} ; \qquad [ 9 ]$$

$$\frac{( {V}_{1} - {V}_{0} ) ( 2 * m * {V}_{1}^{2} )}{{t}_{1} * f ( {attitude}_{1} )} = \frac{( {V}_{2} - {V}_{1} ) ( 2 * m * {V}_{2}^{2} )}{{t}_{2} * f ( {attitude}_{2} )} ; and \qquad [ 10 ]$$

$$\frac{( {V}_{2} - {V}_{1} ) ( {V}_{2}^{2} ) ( {ρ}_{1} ) ( {t}_{1} * f ( {attitude}_{1} ) )}{( {V}_{1} - {V}_{0} ) ( {V}_{1}^{2} ) ( {t}_{2} * f ( {attitude}_{2} ) )} = {ρ}_{2} ; \qquad [ 11 ]$$

where: ρ₁ is the first atmospheric density at the first attitude; ρ₂ is the first atmospheric density at the second attitude; V₁² is the first velocity; V₂² is the second velocity; V₀−V₁ is the first change in velocity; V₁−V₂ is the second change in velocity; m is a mass of the first satellite; t₁ is the first time period; t₂ is the second time period; f(attitude₁) is the first coefficient; and f(attitude₂) is the second coefficient.
4.2 Method: Atmospheric Density from Consecutive Orbits

Generally, the method S100 can include: accessing a first series of mission data of a first satellite traversing a first orbit on a first orbital path at a first altitude and at a first attitude during a first time period in Block S112; and accessing a second series of mission data of the first satellite traversing a second orbit on the first orbital path at the first altitude and at a second attitude during a second time period in Block S114.

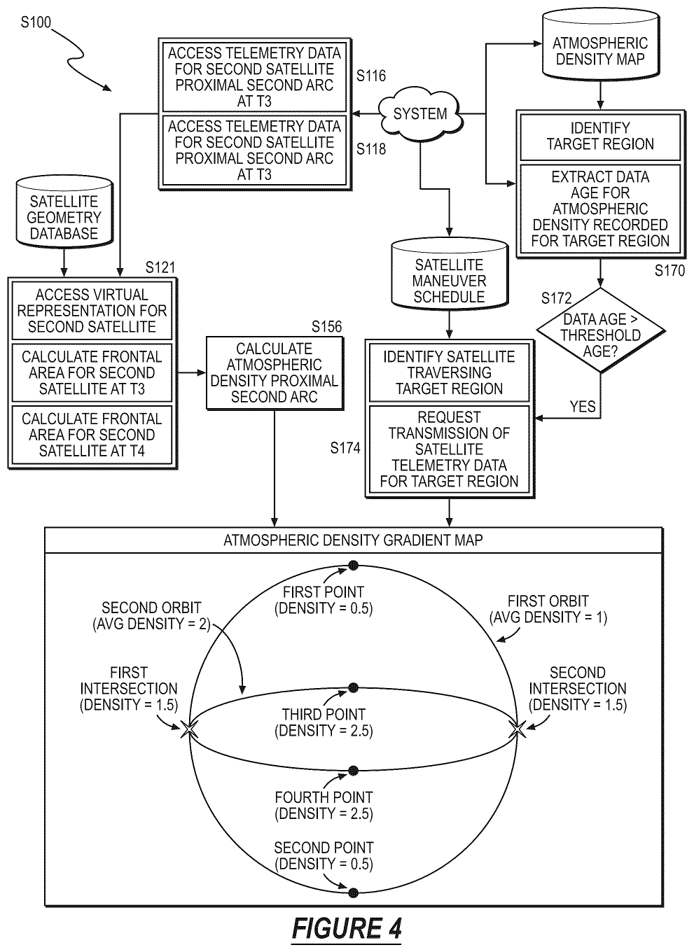

As shown in FIG. 4, in this implementation, the system generates the atmospheric density gradient map (hereinafter referred to as the “map,”) based on mission data from consecutive orbits of a satellite. In particular, in this implementation, the system can: access a first series of mission data of a first satellite traversing a first orbit, on a first orbital path corresponding to a first altitude, at a first attitude; and access a second series of mission data of the first satellite traversing a second orbit, on the first orbital path and succeeding the first orbit, at a second attitude. For example, for each series of mission data, the system can access: position; velocity; altitude; direction of travel; and attitude of the satellite. The system can additionally access identification information about the satellite, such as by accessing a database of satellite operator agreements indicating: a shape model (e.g., a three-dimensional representation) of the satellite, an operator, a maneuver schedule; and operator preferences (e.g., that the system only change the attitude of the satellite once per day).

In one variation, the system can access the first series of mission data by transmitting an instruction to the first satellite to capture the first series of mission data at a first time at which the satellite is at a first attitude, and requesting transmission of the first series of mission data from the satellite to the system. The system can then instruct the first satellite to maneuver from the first attitude to the second attitude. For example, the system can select the second attitude randomly or by calculating a target second attitude based on the three-dimensional representation of the satellite (e.g., an attitude that causes a maximum frontal area change from the first attitude based on the map of the satellite and the first attitude). In this variation, the system can: generate a maneuver instruction to actuate the satellite from the first attitude to the second attitude; transmit the maneuver instruction to the first satellite for execution; and request transmission of the second series of mission data from the satellite at a time during and/or after the attitude change maneuver is executed by the satellite.

Alternatively, in one example, the system can select the second attitude based on a recordation date of mission data exceeding a threshold recordation date defined by the system. In this example, the method S100 can include identifying a target celestial region of the atmospheric density gradient map (e.g., corresponding to the first arc of the first orbital path) corresponding to an initial atmospheric density recorded for the first satellite at an initial time (e.g., 10 days prior to the current time) in Block S170. In this example, Blocks of the method S100 can further include, in response to a recordation date of the initial atmospheric density exceeding a threshold recordation date in Block S172: identifying the first satellite traversing the first orbital path intersecting the target celestial region; generating a command to change attitude from the first attitude to the second attitude; transmitting a maneuver instruction to the first satellite to capture the first series of mission data at the first attitude during the first time period and the second series of mission data at the second attitude during the second time period; and requesting transmission of the first series of mission data and the second series of mission data from the first satellite in Block S174.

In another example, the system can: transmit the maneuver instruction to the first satellite; start a timer; and, in response to the timer expiring, request the second series of mission data. The timer duration allows the satellite to execute the attitude change maneuver and reach a steady state at the second attitude. The mission data during the changing satellite attitude maneuver provides a time-series of atmospheric drag force including a dominant signal of the change in the drag-coefficient and a minor signal of the change in atmospheric density.

### 4.2.1 Data Subset Selection

The method S100 can include: selecting a first subset of mission data, from the first series of mission data, corresponding to a first arc of the first orbital path in Block S142; and selecting a second subset of mission data, from the second series of mission data, corresponding to the first arc of the first orbital path in Block S144. Generally, the system can select subsets of trajectory and attitude data of a satellite, each subset corresponding to a particular orbit of an orbital path.

The system can: select a first subset of mission data, from the first series of mission data, corresponding to a first arc of the first orbital path; and select a second subset of mission data, from the second series of mission data, corresponding to the first arc of the first orbital path. The system selects the first subset from the first series of mission data by: determining a target position of the first satellite or a target time within the first series of mission data; and extracting a data point (e.g., when the satellite is at the target position or at the target time) from the first timeseries of mission data. The system can repeat the steps above in order to select a second subset of mission data from the second series of mission data. The system defines the arc as a segment of the orbit between a first position of the satellite from the first subset of mission data and a second position of the satellite from the second subset of the mission data. For example, an arc can include 1° of a 360° orbit.

### 4.2.2 Atmospheric Density Calculation

The method S100 can include calculating a first atmospheric density proximal the first arc of the first orbital path in Block S152. Generally, the system can access trajectory and attitude data of a satellite before and after an attitude change of the satellite to derive an atmospheric drag of the satellite proximal a celestial location (e.g., latitude, longitude, altitude with a terrestrial coordinate system of the Earth) in Block S152. In one variation, the system can: implement methods and techniques described above to calculate frontal areas of the first satellite based on a virtual representation of the first satellite; and calculate a first atmospheric density proximal the first arc on the first orbital path based on: the first subset of mission data; the second subset of mission data; the first frontal area; and the second frontal area.

In one example, the system can: access the virtual representation of the satellite including a three-dimensional representation of the satellite; access a first series of mission data including a first pitch, a first yaw, a first roll, a first configuration, and a first direction of motion of the satellite traversing a first orbit on a first orbital path at a first altitude and at a first attitude during a first time period; and access a second series of mission data including a second pitch, a second yaw, a second roll, a second configuration, and a second direction of motion of the first satellite traversing a second orbit on the first orbital path at the first altitude and at a second attitude during a second time period.

In this example, to calculate a first frontal area of the first satellite during the first orbit at the first attitude, the system can: select a first plane orthogonal to the first direction of motion in the first series of mission data; orient the three-dimensional representation of the first satellite relative to the first plane based on the first pitch, the first yaw, the first roll, and the first configuration; and project a first two-dimensional representation of the three-dimensional representation of the first satellite onto the first plane. Then, to calculate a second frontal area of the first satellite during the second orbit at the second attitude, the system can: select a second plane orthogonal to the second direction of motion in the second series of mission data; orient the three-dimensional representation of the first satellite relative to the second plane based on the second pitch, the second yaw, the second roll, and the second configuration; and project a second two-dimensional representation of the three-dimensional representation of the first satellite onto the second plane. Therefore the system can calculate a second frontal area of the first satellite during the second orbit based on the first virtual representation of the first satellite and the second attitude.

In another variation described above, the system can derive a function relating attitudes of a satellite to coefficients representing products of frontal areas and coefficients of drag of the satellite. In this variation, the system can: extract a first attitude and a first velocity from the first subset of mission data; extract a second attitude and a second velocity from the second subset of mission data; calculate the first coefficient based on the first attitude; calculate the second coefficient based on the second attitude; and calculate the first atmospheric density proximal the first arc on the first orbital path based on the first velocity, the second velocity, the first coefficient, and the second coefficient.

### 4.2.3 Atmospheric Density Map

The method S100 can include generating an atmospheric density gradient map representing the first atmospheric density proximal the first arc of the first orbital path at the first altitude in Block S162. Generally, the system can: transform mission data into average atmospheric densities on discrete orbits; compile the average atmospheric densities into a (smooth) three-dimensional map representing derived atmospheric densities; and interpolate atmospheric densities around the Earth over a range of altitudes based on the derived atmospheric densities in Block 162.

In one implementation, the system can select a third and fourth subset of mission data from the second series of mission data by executing the steps above in order to select the first and second subsets of mission data. The third and fourth subsets can define endpoints of a second arc. The system can: calculate a second atmospheric density proximal the second arc on the first orbital path based on the third subset of mission data, the fourth subset of mission data, the first frontal area, and the second frontal area; and generate an atmospheric density gradient map representing the first atmospheric density proximal the first arc of the first orbital path at the first altitude and the second atmospheric density proximal the first arc of the first orbital path at the first altitude.

In one variation of the method S100, the system can iteratively execute the process above to calculate multiple density values for an arc. The system can transmit instructions to the satellite to send mission data from: a first time preceding a maneuver to a third attitude in a third consecutive orbit; and a second time following the maneuver to the third attitude. The system can additionally transmit a request to the satellite for mission data from: a third time preceding a maneuver to a fourth attitude in a fourth consecutive orbit; and a fourth time following the maneuver to the fourth attitude. The system can therefore converge on an atmospheric density for an area of the atmosphere (e.g., an arc) based on the first, second, third, fourth, and further subsets of mission data.

### 4.2.4 Estimation Methods

In one variation, the system can access one or more sets of mission data to estimate an atmospheric density of a target region (e.g., calculating a predicted subset of mission data based on mission data and an attitude change, calculating an average atmospheric density along an orbital path, interpolating an atmospheric density near an intersection of two orbital paths, extrapolating a current or future atmospheric density).

In this variation, the system calculates a predicted subset of mission data based on the first subset of mission data and a second attitude. The system can compare the predicted subset of mission data to the actual subset of mission data at the second attitude to: calculate an error value (e.g., of an atmospheric density measurement or drag coefficient estimation) within the map; and update the map with the error value to improve the map accuracy.

In this variation, the method S100 can include: identifying a target celestial region of the atmospheric density gradient map in Block S180; accessing a database including a corpus of satellite mission data and a schedule of planned attitude changes and identifying a second satellite planning to execute an attitude change maneuver in the target celestial region in Block S182; and, at a first time preceding the attitude change maneuver, selecting a target time and a target position in the atmosphere after the attitude change maneuver and estimating a predicted atmospheric density of the second satellite at the target time and the target position in Block S184. In this variation, Blocks of the method S100 can further include, at a second time following the attitude change maneuver: calculating an error value based on a difference detected between the predicted atmospheric density and the actual atmospheric density of the second satellite at the target position in Block S186; and calibrating the atmospheric density gradient map based on the error value in Block S188.

In one example, the system can: identify a target celestial region of the atmospheric density gradient map; access a database including a corpus of satellite mission data and a schedule of planned attitude changes; and identify a second satellite planning to execute an attitude change maneuver in the target celestial region. At a first time preceding the attitude change maneuver, the system can: estimate a predicted atmospheric density of the second satellite at a selected target time and target position in the atmosphere after the attitude change maneuver. Then, at a second time following the attitude change maneuver, the system can: extract an actual atmospheric density of the second satellite at the target time and the target position; detect a difference between the predicted atmospheric density and the actual atmospheric density; calculate an error value based on the difference; and calibrate the atmospheric density gradient map based on the error value.

In another variation, the system can calculate an average atmospheric density along an orbital path by averaging mission data received over the entirety of the orbital path. The system can calculate the average atmospheric density to estimate approximate atmospheric density data for regions lacking explicit atmospheric density data within the atmosphere (e.g., regions devoid of a satellite connected to the system). As shown in FIG. 4, in another variation, the system can interpolate between the atmospheric densities of two orbits with arcs adjacent to a target region to calculate an average atmospheric density of the target region.

In another variation, the system can calculate an intersection of two orbits and derive a density at a target region proximal the intersection based on the calculated atmospheric densities at the intersection. In this variation, the method S100 can include: identifying a target celestial region of the atmospheric density gradient map, the target celestial region corresponding to an intersection between a first arc of a first orbital path and a second arc of a second orbital path in Block S190; and interpolating an atmospheric density at the target celestial region proximal the intersection based on a first atmospheric density calculated for the first arc of the first orbital path and the second atmospheric density calculated for the second arc of the second orbital path in Block S192.

For example, the system can identify a target celestial region of the atmospheric density gradient map (e.g., a region lacking mission data), the target celestial region corresponding to an intersection between a first arc of a first orbital path at a first altitude and a second arc of a second orbital path at a second altitude, higher than the first altitude. The system can then access and/or derive a first atmospheric density for the first arc of the first orbital path and a second atmospheric density for the second arc of the second orbital path; and interpolate a third atmospheric density at the target celestial region proximal the intersection based on the first atmospheric density, derived for the first arc located at an altitude below the target celestial region, and the second atmospheric density, derived for the second arc located at an altitude above the target celestial region. The system can repeat this process to: collect data from satellites at different altitudes; calculate an atmospheric density proximal each celestial location; and compile the atmospheric densities into a (smooth) three-dimensional map representing derived atmospheric densities.

In another variation, the system can extrapolate future atmospheric densities at particular celestial locations based on past and/or current atmospheric density maps. For example, the system can: identify a target celestial region of the atmospheric density gradient map (e.g., a target position corresponding to a planned future maneuver for a satellite), the target celestial region corresponding to a first arc of a first orbital path at a first altitude; and access an atmospheric density gradient map representing a first initial atmospheric density proximal the first arc during a first time period (e.g., data collected 5 days prior to the current time) and a second initial atmospheric density proximal the first arc during a second time period (e.g., data collected 10 days prior to the current time). Then, for a third time (e.g., a future time corresponding to the planned future maneuver for the satellite), the system can extrapolate a third atmospheric density proximal the first arc of the first orbital path based on the first initial atmospheric density and the second initial atmospheric density.

Therefore, the system can: derive atmospheric densities near many celestial locations; compile these atmospheric densities into a three-dimensional map of atmospheric densities based on their corresponding celestial locations; and interpolate an atmospheric density between these derived atmospheric densities to form a gradient or mesh of current atmospheric densities within this three-dimensional atmospheric density map. The system can additionally or alternatively: repeat this process to create multiple three-dimensional atmospheric density maps over time based on trajectory and attitude data of these satellites, such as collected within discrete time intervals; and can extrapolate future atmospheric densities at particular celestial locations based on past and/or current atmospheric density maps.

4.3 Method: Atmospheric Density for Consecutive Arcs within a Single Orbit

In another variation, the method S100 can include: selecting a third subset of mission data, from the first series of mission data, corresponding to a second arc of the first orbital path in Block S146; selecting a fourth subset of mission data, from the second series of mission data, corresponding to the second arc of the first orbital path in Block S148; and calculating a second atmospheric density proximal the second arc of the first orbital path based on the third subset of mission data, the fourth subset of mission data, the first frontal area, and the second frontal area in Block S154. Generally, the system can select subsets of trajectory and attitude data of a satellite, each subset corresponding to a particular arc of an orbital path.

As shown in FIGS. 1 and 2, in this implementation, the system can calculate atmospheric density based on mission data from consecutive arcs (e.g., segments of an orbit) of a single orbit. In this implementation, the system can define a first arc of a first orbital path including a first segment of the first orbital path and further define a second arc of the first orbital path, the second arc including a second segment of the first orbital path distinct from the first segment of the first orbital path.

In particular, in this implementation, the system can: select a first subset of mission data, from a first series of mission data, corresponding to a first satellite traversing the first arc during a first orbit on the first orbital path at a first attitude during a first time period; select a second subset of mission data, from a second series of mission data, corresponding to the first satellite traversing the first arc during a second orbit on the first orbital path at a second attitude during a second time period; select a third subset of mission data, from the first series of mission data, corresponding to the first satellite traversing the second arc during the first orbit; and fourth subset of mission data, from the second series of mission data corresponding to the first satellite traversing the second arc during the second orbit.

In one variation, the system can implement methods and techniques described above to transmit a maneuver instruction to a satellite for the satellite to maneuver from a first attitude to a second attitude within two consecutive arcs of an orbit (e.g., an arc from 0° to 1° latitude and an arc from 1° to 2° latitude along the 0° longitude line); and receive transmission of the first and second series of mission data from the satellite. Therefore, the system can calculate multiple atmospheric densities at different arcs within a single orbit.

For example, the system can: access a first series of mission data of a first satellite traversing a first arc of a first orbit, on an first orbital path corresponding to a first altitude, at a first attitude; access a second series of mission data of the first satellite traversing a second arc of the first orbit, adjacent and succeeding the first arc, at a second attitude; access a first virtual representation of the first satellite; calculate a first frontal area of the first satellite traversing the first arc of the first orbit based on the first virtual representation of the first satellite and first attitude; and calculate a second frontal area of the first satellite traversing the second arc of the first orbit based on the first virtual representation of the first satellite and second attitude.

The system can then calculate a first average atmospheric density across a first composite arc, including the first arc and the second arc, on the first orbital path based on: the first series of mission data; the second series of mission data; the first frontal area; and the second frontal area. The system can then generate an atmospheric density gradient map representing the first average atmospheric density proximal the first composite arc of the first orbital path at the first altitude.

### 4.3.1 Variation: Second Satellite

In one variation, the method S100 can include: accessing a third series of mission data of a second satellite traversing a third orbit, on a second orbital path at a second altitude and at a third attitude during a third time period in Block S116; accessing a fourth series of mission data of the second satellite traversing a fourth orbit, on the second orbital path at a fourth attitude during a fourth time period in Block S118; calculating a third and fourth frontal area of the second satellite based on a second virtual representation of the second satellite in Block S121; and calculating a second atmospheric density proximal the second arc on the second orbital path based on the third subset of mission data, the fourth subset of mission data, the third frontal area, and the fourth frontal area in Block S156.

The system can additionally repeat the method to collect: a third series of mission data of a second satellite traversing a third arc of a second orbit, on a second orbital path corresponding to a second altitude, at a second attitude; and a fourth series of mission data of the second satellite traversing a fourth arc of the second orbit, adjacent and succeeding the third arc, at a second attitude. The system can then calculate the third and fourth frontal areas of the satellite based on the three-dimensional representation of the satellite and a third and fourth attitude. The system can then calculate a second average atmospheric density across a second composite arc, including the third arc and the fourth arc, on the second orbital path based on: the third series of mission data; the fourth series of mission data; the third frontal area; and the fourth frontal area. In this variation, the method can further include generating the atmospheric density gradient map that further represents the second average atmospheric density proximal the second composite arc of the second orbital path at the second altitude.

### 4.4 Method Variations

The system can execute the method to derive atmospheric densities of an arc of a single orbit or full consecutive orbits. In one implementation, the system can decouple atmospheric density and the drag coefficient, based on the assumption of constant atmospheric density throughout an arc or orbit. For example, the system solves for the drag coefficient via equation [1] by holding density constant for two sets of mission data.

In another implementation, the system decouples atmospheric density by determining: a first proportion (e.g., 95%) of the change in drag related to a change of the drag coefficient from a first attitude to a second attitude of the satellite; and a second proportion (e.g., 5%) of the change in drag related to the change of atmospheric density from a first position to a second position of the satellite. For example, the system can: derive a value of the change in drag force on the satellite based on the first and second mission data sets; and calculate a change in density and a change in drag coefficient based on the change of drag force and the first and second proportions.

### 4.5 Control Variations

The system can passively and/or actively collect mission data to calculate atmospheric densities. The examples described above for calculating atmospheric densities with consecutive orbit mission data and with consecutive arc mission data include active control steps. For example, the system transmits maneuver instructions for the satellite to change from a first attitude to a second attitude, thereby actively controlling the satellite. The system can additionally passively access mission data from a population of satellites, such as by accessing a database of mission data streamed from a population of satellites.

In one implementation, the system can passively access mission data based on a satellite maneuver schedule. For example, the system can access a satellite maneuver schedule indicating times and coordinates within the atmosphere during which that satellite will execute a maneuver to change attitude. The system accesses the satellite maneuver schedule and selects a reference time and/or position in the atmosphere that a satellite is scheduled to change attitude from a first attitude to a second attitude. The system then selects a first target time and/or position in the atmosphere before the attitude change maneuver is executed (e.g., at a first time); selects a first mission data point of the satellite at the first target time and position; selects a second target time and position in the atmosphere after the attitude change maneuver; waits for the satellite to complete the attitude change maneuver to a second attitude (e.g., by setting a timer from the first target time to the second target time); and selects a second mission data point of the satellite at the second target time and/or position in the atmosphere. The system can then execute the method described above to calculate an atmospheric density between the first and second positions of the satellite.

Additionally or alternatively, in another implementation, the system can passively access mission data without a satellite maneuver schedule. For example, the system can access a real-time stream of data from a satellite or database of near real-time (e.g., 10 minutes delayed) satellite data. The system can: monitor mission data from the stream or database (e.g., access a data point twice per hour); detect a change in attitude of the satellite by comparing a first mission data point to a second mission data point; detect a time of the attitude change maneuver from the mission data; select a first mission data point from a first time preceding (e.g., 5 minutes before) the time of the attitude change maneuver; and select a second mission datapoint from a second time following (e.g., 5 minutes after) the attitude change maneuver. The system can then calculate the atmospheric density along the arc the satellite travelled between the first time and the second time via the method described above.

### 5. Map Maintenance

The system can maintain the map (e.g., the atmospheric density gradient map) by updating the data in the map at a threshold frequency. For example, the system can: retain an atmospheric density in the map for up to 15 days; and update densities in different regions of the map based on new mission data. In one variation, the system can modify an atmospheric density with an error bar based on the recordation date (e.g., 1-15 days) of the mission data via which the atmospheric density was calculated. For example, the system can display a notification to a user interacting with the module (e.g., via an application or website on a computing device), the notification indicating a recordation date of an atmospheric density within the map and modifying the atmospheric density with an error bar (e.g., +/−5% per day of the recordation date of the atmospheric density).

The system can additionally generate scheduled attitude changes and/or mission data requests based on the recordation date of atmospheric densities within the map. For example, the system can schedule an attitude change to collect mission data for a region of the map with an atmospheric density based on mission data collected 5 days prior to the current time. The system can then select a satellite that travels through the region and collect mission data from that satellite within the region to update the atmospheric density of the region of the map.

The system can further apply weights to the mission data based on when it was accessed by the system. For example, the system can apply a highest weight a newest mission data point for a region within the map and apply a lowest weight to an oldest mission data point within the map. Therefore, the map is configured to present atmospheric densities based on mission data collected most recently.

### 6. Map Applications

The system can store a history of the map (e.g., retain a copy of each atmospheric density calculated within 1 day). The system extracts the historical map data to detect trends in the map and predict future maps. For example, the system can predict a future (e.g., 10-day forecast) map based on a weather forecast within the 10-day period, and recent historical map data. The system can therefore predict a trajectory of a satellite based on accurate atmospheric density predictions.

The system can execute the method to: generate a near real-time atmospheric density model; and update the atmospheric density model based on new mission data. The system can additionally execute the method to: calibrate a pre-existing model by calculating a correction value of an atmospheric density value within the pre-existing model and updating the pre-existing model with the correction value.

### 7. Conclusion

The systems and methods described herein can be embodied and/or implemented at least in part as a machine configured to receive a computer-readable medium storing computer-readable instructions. The instructions can be executed by computer-executable components integrated with the application, applet, host, server, network, website, communication service, communication interface, hardware/firmware/software elements of a user computer or mobile device, wristband, smartphone, or any suitable combination thereof. Other systems and methods of the embodiment can be embodied and/or implemented at least in part as a machine configured to receive a computer-readable medium storing computer-readable instructions. The instructions can be executed by computer-executable components integrated by computer-executable components integrated with apparatuses and networks of the type described above. The computer-readable medium can be stored on any suitable computer readable media such as RAMs, ROMs, flash memory, EEPROMs, optical devices (CD or DVD), hard drives, floppy drives, or any suitable device. The computer-executable component can be a processor, but any suitable dedicated hardware device can (alternatively or additionally) execute the instructions.

As a person skilled in the art will recognize from the previous detailed description and from the figures and claims, modifications and changes can be made to the embodiments of the invention without departing from the scope of this invention as defined in the following claims.

I claim:

1. A method comprising:
accessing a first series of mission data of a first satellite traversing a first orbit on a first orbital path at a first altitude and at a first attitude during a first time period;
accessing a second series of mission data of the first satellite traversing a second orbit on the first orbital path at the first altitude and at a second attitude during a second time period;
accessing a first virtual representation of the first satellite;
calculating a first frontal area of the first satellite during the first orbit based on the first virtual representation of the first satellite and the first attitude;
calculating a second frontal area of the first satellite during the second orbit based on the first virtual representation of the first satellite and the second attitude;
selecting a first subset of mission data, from the first series of mission data, corresponding to a first arc of the first orbital path;
selecting a second subset of mission data, from the second series of mission data, corresponding to the first arc of the first orbital path;
calculating a first atmospheric density proximal the first arc of the first orbital path based on:
the first subset of mission data;
the second subset of mission data;
the first frontal area; and
the second frontal area; and
generating an atmospheric density gradient map representing the first atmospheric density proximal the first arc of the first orbital path at the first altitude.

2. The method of claim 1:
further comprising:
defining the first arc of the first orbital path comprising a first segment of the first orbital path;
defining a second arc of the first orbital path, the second arc comprising a second segment of the first orbital path distinct from the first segment of the first orbital path;
selecting a third subset of mission data, from the first series of mission data, corresponding to a second arc of the first orbital path;
selecting a fourth subset of mission data, from the second series of mission data, corresponding to the second arc of the first orbital path; and
calculating a second atmospheric density proximal the second arc of the first orbital path based on:
the third subset of mission data;
the fourth subset of mission data;
the first frontal area; and
the second frontal area; and
wherein generating the atmospheric density gradient map comprises generating the atmospheric density gradient map that further represents the second atmospheric density proximal the second arc of the first orbital path at the first altitude.

3. The method of claim 1:
further comprising defining the first arc of the first orbital path comprising an entirety of the first orbital path; and
wherein calculating the first atmospheric density comprises calculating the first atmospheric density representing a first average atmospheric density along the first orbital path.

4. The method of claim 1:
wherein accessing the first virtual representation of the first satellite comprises accessing a three-dimensional representation of the first satellite;
wherein accessing the first series of mission data comprises accessing:
a first pitch;
a first yaw;
a first roll;
a first configuration; and
a first direction of motion of the first satellite at the first attitude during the first time period;
wherein accessing the second series of mission data comprises accessing:
a second pitch;
a second yaw;
a second roll;
a second configuration; and
a second direction of motion of the first satellite at the second attitude during the second time period;
wherein calculating the first frontal area of the first satellite during the first orbit at the first attitude comprises:
selecting a first plane orthogonal to the first direction of motion in the first series of mission data;
orienting the three-dimensional representation of the first satellite relative to the first plane based on the first pitch, the first yaw, the first roll, and the first configuration; and
projecting a first two-dimensional representation of the three-dimensional representation of the first satellite onto the first plane; and
wherein calculating the second frontal area of the first satellite during the second orbit at the second attitude comprises:
selecting a second plane orthogonal to the second direction of motion in the second series of mission data;
orienting the three-dimensional representation of the first satellite relative to the second plane based on the second pitch, the second yaw, the second roll, and the second configuration; and
projecting a second two-dimensional representation of the three-dimensional representation of the first satellite onto the second plane.

5. The method of claim 4, wherein calculating the first atmospheric density comprises:
deriving a first angular acceleration and a first velocity of the first satellite traversing the first arc at the first attitude during the first time period from the first subset of mission data;
deriving a first atmospheric drag force on the first satellite traversing the first arc at the first attitude during the first time period based on the first angular acceleration;
deriving a second angular acceleration and a second velocity of the first satellite traversing the first arc at the second attitude during the second time period from the second subset of mission data;
deriving a second atmospheric drag force on the first satellite traversing the first arc at the second attitude during the second time period based on the second angular acceleration;
solving for a drag coefficient based on:
the first atmospheric density;
the first atmospheric drag force;
the second atmospheric drag force;
the first frontal area;
the second frontal area;
the first velocity; and
the second velocity; and
calculating the first atmospheric density based on the drag coefficient.

6. The method of claim 1:
further comprising, at an initial time preceding the first time period and the second time period:
identifying a target celestial region of the atmospheric density gradient map, the target celestial region corresponding to the first arc of the first orbital path and an initial atmospheric density proximal the first arc of the first orbital path at the initial time;
in response to a recordation date of the initial atmospheric density exceeding a threshold data recordation date:
identifying the first satellite traversing the first orbital path intersecting the target celestial region;
generating a maneuver instruction to change attitude from the first attitude to the second attitude;
transmitting the maneuver instruction to the first satellite to capture the first series of mission data at the first attitude during the first time period and the second series of mission data at the second attitude during the second time period; and
requesting transmission of the first series of mission data and the second series of mission data from the first satellite; and
wherein generating the atmospheric density gradient map comprises generating the atmospheric density gradient map replacing the initial atmospheric density with the first atmospheric density.

7. The method of claim 1, further comprising:
identifying a target celestial region of the atmospheric density gradient map;
accessing a database comprising a corpus of satellite mission data and a schedule of planned attitude changes;
identifying a second satellite planning to execute an attitude change maneuver in the target celestial region;
at a first time preceding the attitude change maneuver:
selecting a target time and a target position in the atmosphere after the attitude change maneuver; and
estimating a predicted atmospheric density of the second satellite at the target time and the target position; and
at a second time following the attitude change maneuver:
extracting an actual atmospheric density of the second satellite at the target time and the target position;
detecting a difference between the predicted atmospheric density and the actual atmospheric density;
calculating an error value based on the difference; and
calibrating the atmospheric density gradient map based on the error value.

8. The method of claim 2, further comprising:
identifying a target celestial region of the atmospheric density gradient map, the target celestial region corresponding to an intersection between the first arc of the first orbital path and the second arc of the second orbital path; and
interpolating a third atmospheric density at the target celestial region proximal the intersection based on the first atmospheric density and the second atmospheric density.

9. The method of claim 1, further comprising:
accessing a third series of mission data of a second satellite traversing a third orbit, on a second orbital path at a second altitude and at a third attitude during a third time period;
accessing a fourth series of mission data of the second satellite traversing a fourth orbit, on the second orbital path at a fourth attitude during a fourth time period;
accessing a second virtual representation of the second satellite;
calculating a third frontal area of the second satellite during the third orbit based on the second virtual representation of the second satellite and the third attitude;
calculating a fourth frontal area of the second satellite during the fourth orbit based on the second virtual representation of the second satellite and the fourth attitude;
selecting a third subset of mission data, from the third series of mission data, corresponding to a second arc of the second orbital path;
selecting a fourth subset of mission data, from the fourth series of mission data, corresponding to the second arc of the second orbital path;
calculating a second atmospheric density proximal the second arc on the second orbital path based on:
the third subset of mission data;
the fourth subset of mission data;
the third frontal area; and
the fourth frontal area; and
generating the atmospheric density gradient map that further represents the second atmospheric density proximal the second arc of the second orbital path at the second altitude.

10. The method of claim 1:
wherein generating the atmospheric density gradient map comprises generating the atmospheric density gradient map representing the first atmospheric density proximal the first arc of the first orbital path at the first altitude during the first time period and the second time period; and
further comprising:
accessing an initial atmospheric density gradient map representing an initial atmospheric density proximal the first arc of the first orbital path at an initial time preceding the first time period and the second time period; and
at a third time exceeding the initial time, the first time period, and the second time period, extrapolating a third atmospheric density proximal the first arc of the first orbital path based on the initial atmospheric density and the first atmospheric density.

11. A method comprising:
accessing a first series of mission data of a first satellite traversing a first orbit on a first orbital path at a first altitude and at a first attitude during a first time period;
accessing a second series of mission data of the first satellite traversing a second orbit on the first orbital path at the first altitude and at a second attitude during a second time period;
accessing a first function relating attitudes of the first satellite to coefficients representing products of frontal areas and coefficients of drag of the first satellite;
calculating a first coefficient of the first satellite during the first orbit based on the first function and the first attitude;
calculating a second coefficient of the first satellite during the second orbit based on the first function and the second attitude;
selecting a first subset of mission data, from the first series of mission data, corresponding to a first arc of the first orbital path;
selecting a second subset of mission data, from the second series of mission data, corresponding to the first arc of the first orbital path;
calculating a first atmospheric density proximal the first arc on the first orbital path based on:
the first subset of mission data;
the second subset of mission data;
the first coefficient; and
the second coefficient; and
generating an atmospheric density gradient map representing the first atmospheric density proximal the first arc of the first orbital path at the first altitude.

12. The method of claim 11:
further comprising:
accessing a third series of mission data of the first satellite traversing a third orbit on the first orbital path at the first altitude and at a third attitude during a first calibration period, the third series of mission data comprising:
a third velocity;
a third yaw;
a third pitch;
a third roll; and
a third configuration;
accessing a fourth series of mission data of the first satellite traversing a fourth orbit on the first orbital path at the first altitude and at a fourth attitude during the second calibration period, the fourth series of mission data comprising:
a fourth velocity;
a fourth yaw;
a fourth pitch;
a fourth roll; and
a fourth configuration;
detecting a change in frontal area of the first satellite between the third attitude and the fourth attitude based on:
the third yaw;
the third pitch;
the third roll;
the third configuration;
the fourth yaw;
the fourth pitch;
the fourth roll; and
the fourth configuration;
deriving the first function based on:
the third velocity;
the fourth velocity; and
the change in frontal area of the first satellite;
wherein accessing the first series of mission data comprises accessing:
a first velocity;
a first yaw;
a first pitch;
a first roll; and
a first configuration during the first time period; and
wherein calculating the first coefficient comprises calculating the first coefficient based on:
the first function;
the first velocity;
the first yaw;
the first pitch;
the first roll; and
the first configuration during the first time period.

13. The method of claim 12:
wherein accessing the first series of mission data comprises accessing a first change in velocity of the first satellite traversing the first orbit;
wherein accessing the second series of mission data comprises accessing a second change in velocity of the first satellite traversing the second orbit; and
wherein calculating the first atmospheric density comprises calculating the first atmospheric density based on:
$$\frac{( {V}_{1} - {V}_{0} ) ( 2 * m * {V}_{1}^{2} )}{{t}_{1} * f ( {attitude}_{1} )} = {ρ}_{1} ;$$
$$\frac{( {V}_{2} - {V}_{1} ) ( 2 * m * {V}_{2}^{2} )}{{t}_{2} * f ( {attitude}_{2} )} = {ρ}_{2} ;$$
$${ρ}_{1} = {ρ}_{2} ;$$
$$\frac{( {V}_{1} - {V}_{0} ) ( 2 * m * {V}_{1}^{2} )}{{t}_{1} * f ( {attitude}_{1} )} = \frac{( {V}_{2} - {V}_{1} ) ( 2 * m * {V}_{2}^{2} )}{{t}_{2} * f ( {attitude}_{2} )} ; and$$
$$\frac{( {V}_{2} - {V}_{1} ) ( {V}_{2}^{2} ) ( {ρ}_{1} ) ( {t}_{1} * f ( {attitude}_{1} ) )}{( {V}_{1} - {V}_{0} ) ( {V}_{1}^{2} ) ( {t}_{2} * f ( {attitude}_{2} ) )} = {ρ}_{2} ;$$
given:
V₀−V₁=the first change in velocity;
V₁−V₂=the second change in velocity;
m=a mass of the first satellite;
V₁²=the first velocity,
V₂²=the second velocity;
t₁=the first time period;
t₂=the second time period;
f(attitude₁)=the first coefficient;
f(attitude₂)=the second coefficient;
ρ₁=the first atmospheric density at the first attitude; and
ρ₂=the first atmospheric density at the second attitude.

14. The method of claim 11:
further comprising:
defining the first arc of the first orbital path comprising a first segment of the first orbital path;
defining a second arc of the first orbital path, the second arc comprising a second segment of the first orbital path distinct from the first segment of the first orbital path;
selecting a third subset of mission data, from the first series of mission data, corresponding to a second arc of the first orbital path;
selecting a fourth subset of mission data, from the second series of mission data, corresponding to the second arc of the first orbital path;
calculating a second atmospheric density proximal the second arc of the first orbital path based on:
the third subset of mission data;
the fourth subset of mission data;
the first frontal area; and
the second frontal area; and
wherein generating the atmospheric density gradient map comprises generating the atmospheric density gradient map that further represents the second atmospheric density proximal the second arc of the first orbital path at the first altitude.

15. The method of claim 11:
further comprising defining the first arc of the first orbital path comprising an entirety of the first orbital path; and
wherein calculating the first atmospheric density comprises calculating the first atmospheric density representing a first average atmospheric density along the first orbital path.

16. The method of claim 11, further comprising:
identifying a target celestial region of the atmospheric density gradient map, the target celestial region;
accessing a database comprising a corpus of satellite mission data and a schedule of planned attitude changes;
identifying a second satellite planning to execute an attitude change maneuver in the target celestial region;
at a first time preceding the attitude change maneuver:
selecting a target time and a target position in the atmosphere after the attitude change maneuver; and
estimating a predicted atmospheric density of the second satellite at the target time and the target position; and
at a second time following the attitude change maneuver:
extracting an actual atmospheric density of the second satellite at the target time and the target position;
detecting a difference between the predicted atmospheric density and the actual atmospheric density;
calculating an error value based on the difference; and
calibrating the atmospheric density gradient map based on the error value.

17. The method of claim 16, further comprising:
identifying a target celestial region of the atmospheric density gradient map, the target celestial region corresponding to an intersection between the first arc of the first orbital path and the second arc of the second orbital path; and
interpolating a third atmospheric density at the target celestial region proximal the intersection based on the first atmospheric density and the second atmospheric density.

18. The method of claim 11:
wherein generating the atmospheric density gradient map comprises generating the atmospheric density gradient map representing the first atmospheric density proximal the first arc of the first orbital path at the first altitude during the first time period and the second time period; and
further comprising:
accessing an initial atmospheric density gradient map representing an initial atmospheric density proximal the first arc of the first orbital path at an initial time preceding the first time period and the second time period; and
at a third time exceeding the initial time, the first time period, and the second time period, extrapolating a third atmospheric density proximal the first arc of the first orbital path based on the initial atmospheric density and the first atmospheric density.

19. The method of claim 11, further comprising:
accessing a third series of mission data of a second satellite traversing a third orbit, on a second orbital path at a second altitude and at a third attitude during a third calibration period the third series of mission data comprising:
a third velocity;
a third yaw;
a third pitch;
a third roll; and
a third configuration;
accessing a fourth series of mission data of the second satellite traversing a fourth orbit, on the second orbital path at a fourth attitude during a fourth calibration period the fourth series of mission data comprising:
a fourth velocity;
a fourth yaw;
a fourth pitch;
a fourth roll; and
a fourth configuration;
detecting a change in area of the second satellite between the third attitude and the fourth attitude based on:
the third yaw;
the third pitch;
the third roll;
the third configuration;
the fourth yaw;
the fourth pitch;
the fourth roll; and
the fourth configuration; and
calibrating the first function based on:
the third velocity;
the fourth velocity; and
the change in area of the second satellite.
